(19) United States
(12) Patent Application Publication
(10) Pub. No.: US 2012/0274402 A1
(43) Pub. Date: Nov. 1, 2012

(54) HIGH ELECTRON MOBILITY TRANSISTOR

(75) Inventor: CHRISTOPHER BOGUSLAW KOCON, MOUNTAIN TOP, PA (US)

(73) Assignee: TEXAS INSTRUMENTS INCORPORATED, Dallas, TX (US)

(21) Appl. No.: 13/455,626

(22) Filed: Apr. 25, 2012

Related U.S. Application Data
(60) Provisional application No. 61/479,050, filed on Apr. 26, 2011.

(51) Int. Cl. H03F 3/16; H01L 29/778

(52) U.S. Cl. 330/277; 257/76; 257/E29.246

(57) ABSTRACT

A high electron mobility transistor (HEMT) includes a substrate, a heterojunction on the substrate including a first layer having a Group III-nitride semiconductor material interfaced to a second layer having a doped Group III-nitride semiconductor material. A gate electrode is on a surface of the heterojunction, and a source and a drain are on opposite sides of said gate electrode. A patterned field shaping (FS) layer formed from a wide band-gap semiconductor material is over the heterojunction on at least a portion between the gate electrode and the drain.

### CROSS REFERENCE TO RELATED APPLICATIONS

This application claims the benefit of Provisional Application Ser. No. 61/479,050 entitled “HEMT Structure”, filed Apr. 26, 2011, which is herein incorporated by reference in its entirety.

### FIELD

Disclosed embodiments relate to High Electron Mobility Transistors (HEMTs) having electric field shaping.

### BACKGROUND

A high electron mobility transistor (HEMT), also known as heterostructure field effect transistor (HFET) or modulation-doped FET (MODFET), is a FET incorporating a junction between two semiconductor materials with different band-gaps (i.e., a heterojunction) as the channel instead of a doped region, as is generally the case for a metal-oxide-semiconductor FET (MOSFET). In recent years, HEMTs including gallium nitride (GaN) which has a 25° C. band-gap of about 3.4 eV, such as having AlGaN/GaN heterojunctions, have attracted attention due to their superior high-power performance as compared to lower band-gap standard semiconductor-based devices, such as based on Si or GaAs.

Conventional power devices based on HEMTs have been limited in their applications due to long-term reliability issues, including deterioration of their breakdown voltage (BV) and on-resistance (Ron) during field operation. The dominant mode of deterioration is known to be caused by the high electric field at the edge of gate electrode and in the two-dimensional electron gas (2DEG) conducting channel. The 2DEG channel is a “gas” of electrons free to move in two-dimensions, but is tightly confined in the third (axial) dimension. The analogous devices construct relying on a gas of holes is referred to as a 2 dimensional hole gas (2DHG).

High electric fields at the gate corner on the drain side and at the 2DEG or 2DHG channel surface can result in charge trapping and hot carrier injection into the passivation layer which is generally on top of polarization AlGaN layer. The passivation layer typically comprises silicon nitride because silicon nitride can withstand higher electric fields as compared to other dielectrics, such as silicon oxide. Leakage of the HEMT can also increase with field use resulting in higher losses, or the limiting of the maximum reverse blocking voltage rating of the HEMT.

Conventional solutions to the high electric field problem for HEMTs include use of field plates to improve the electric field distribution by pushing the electric fields away from the surface of the HEMT. A “field plate” is a structure that includes an electrode on a dielectric material. The electrode can generally be any electrically conductive material, such as a metal, metal alloy, or heavily doped polysilicon. The dielectric for the field plate is generally silicon nitride passivation due to its ability to withstand the potential difference between the field plate electrode and underlying GaN material (e.g., GaN or AlGaN).

### SUMMARY

Disclosed embodiments include high electron mobility transistors (HEMTs) which include a patterned field shaping (FS) layer which comprises a wide band-gap semiconductor material which selectively applies mechanical stress to the HEMT surface under the FS and to the two dimensional electron gas (2DEG) channel or 2 dimensional hole gas (2DHG) channel under the FS. As used herein, a wide band-gap material is defined as a material having a band-gap of at least 1.4 eV at 25° C., such as a band-gap of at least 2.0 eV at 25° C. in most embodiments.

Disclosed patterned FS layers comprise a wide band-gap material as opposed to metal or heavily doped polysilicon used for conventional field plates, and can comprise undoped or doped wide band-gap materials, such as undoped GaN, p-type GaN, n-type GaN, or another wide band-gap material. As described herein, disclosed FS layers apply mechanical stress to employ the piezoelectric effect which directs the electric field away from the HEMT surface and adjusts the 2DEG or 2DHG channel densities throughout the voltage supporting region between gate and source and the gate and drain, resulting in an improved voltage distribution and reduced electric field at the surface which improves HEMT reliability due to reduced hot carrier injection. In one embodiment, the FS layer is directly on the heterojunction, such as directly on top of the polarization generation layer (e.g., AlGaN), which maximizes the piezoelectric effect provided to the heterojunction. In another embodiment, the FS layer is not directly on the heterojunction, such as being on top of silicon nitride passivation.

In some embodiments disclosed HEMTs further improve the electric field distribution by using zones/FS layer portions having varying FS layer thicknesses. The patterned FS layer can include at least two different thicknesses including a thicker portion closer to the gate region on the drain side as compared to a thinner portion further from the gate region on the drain side. A thicker FS layer portion closer to the gate region on the drain side can lower the electric field at the gate corner and at the 2DEG or 2DHG surface to eliminate or at least significantly reduce charge trapping and hot carrier injection into the passivation layer (such as silicon nitride) on the surface of the polarization generation layer of the heterojunction.

### BRIEF DESCRIPTION OF THE DRAWINGS

Reference will now be made to the accompanying drawings, which are not necessarily drawn to scale, wherein:

FIG. 1A is a cross-sectional depiction of an example HEMT having a patterned FS layer directly on the heterojunction, according to an example embodiment.

FIG. 1B is a cross-sectional depiction of an example HEMT having a patterned FS layer directly on the heterojunction, according to another example embodiment.

FIG. 1C is a cross-sectional depiction of an example HEMT having a patterned FS layer directly on the heterojunction, according to yet another example embodiment.

FIG. 1D is a cross-sectional depiction of an example HEMT having a patterned FS layer directly on the heterojunction, embodied as a metal-oxide-semiconductor (MOS) gate HEMT, according to yet another example embodiment.

FIG. 2A is a cross-sectional depiction of an example HEMT having a passivation layer on the HEMT including directly on the heterojunction between the gate electrode and the source and between the gate electrode and the drain, where the patterned FS layer is on the passivation layer, according to an example embodiment.

FIG. 2B is a cross-sectional depiction of an example HEMT having a passivation layer on the HEMT including directly on the heterojunction between the gate electrode and the source and between the gate electrode and the drain, where the patterned FS layer is on the passivation layer, according to another example embodiment.

FIG. 2C is a cross-sectional depiction of an example HEMT having a passivation layer on the HEMT including directly on the heterojunction between the gate electrode and the source, and between the gate electrode and the drain, where the patterned FS layer is on the passivation layer, according to yet another example embodiment.

FIG. 3 is a block diagram of a power amplifier formed on a substrate showing power amplifier stages including at least one disclosed HEMT in its output stage.

FIGS. 4A and 4B show the structure of a disclosed HEMT having a FS layer comprising GaN that is 50 A thick except next to the gate electrode where it is 150 A thick, and simulation results for this HEMT showing the voltage distribution along the voltage supporting region, respectively, according to an example embodiment.

FIG. 5 show simulated reverse breakdown voltage results for the HEMT shown in FIG. 4A and some control HEMTs that evidence a significant reverse breakdown voltage and leakage improvement for the disclosed HEMTs.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

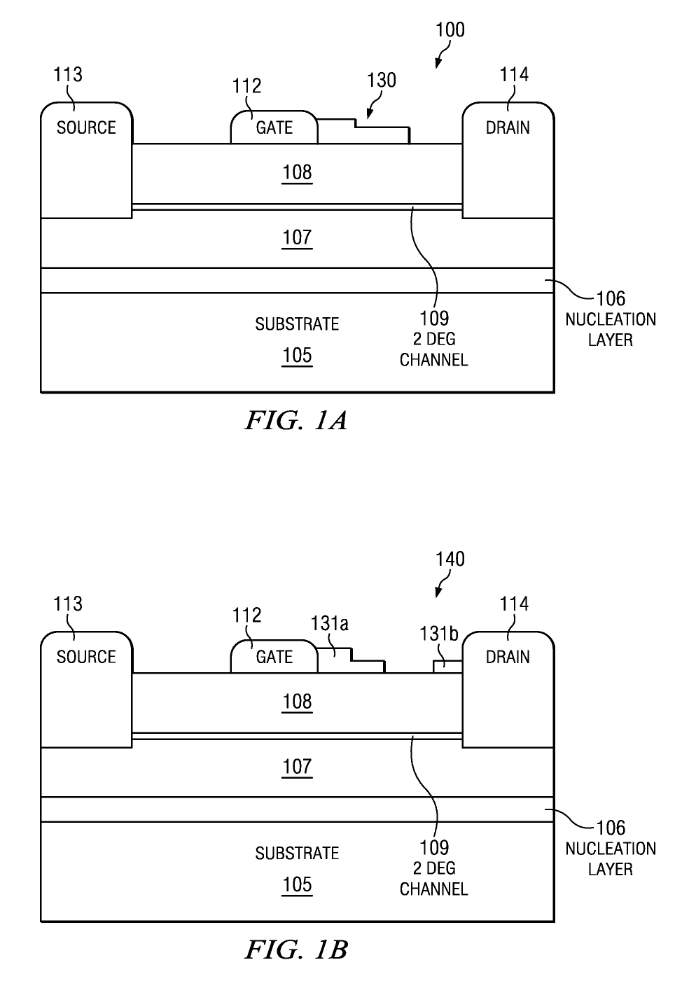

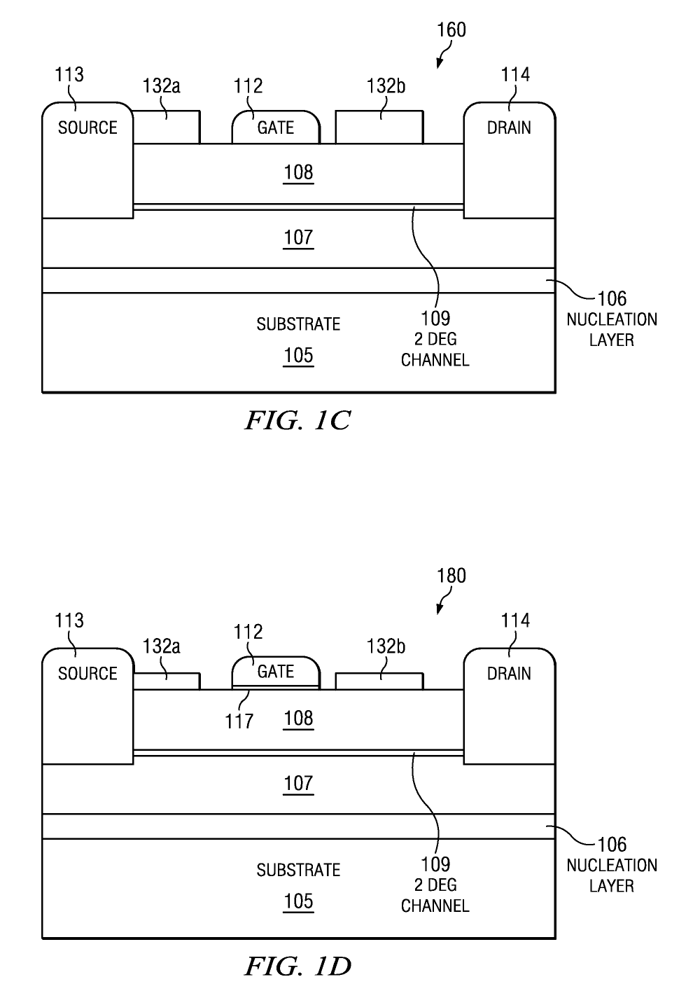

FIG. 1A is a cross-sectional depiction of a HEMT 100 having a patterned FS layer 130 comprising a wide band-gap material shown directly on a heterojunction 108/107 according to an example embodiment. Disclosed HEMTs including HEMT 100 can be either enhancement mode or depletion mode devices. HEMT 100 includes a substrate 105 and a heterojunction 108/107 on the substrate including a first layer 107 comprising Group III-nitride semiconductor material interfaced to a second layer 108 comprising a doped Group III-nitride semiconductor material.

As used herein, a “Group III nitride semiconductor” is defined to be a wide band-gap semiconductor material which is represented by the formula AlₓGa_{y}In_{z}N (x+y+z=1, 0≦x, y, z≦1); such a semiconductor in which a portion of Al, Ga, or In is substituted by another Group 13 element (i.e., B or Tl), or a portion of N is substituted by another Group 15 element (i.e., P, As, Sb, or Bi). Particular examples of the Group III nitride semiconductor include those containing at least Ga, such as GaN, InGaN, AlGaN, and AlGaInN. In one embodiment the Group III nitride semiconductor material comprises GaN on AlGaN(N-face). In another embodiment the Group III nitride semiconductor material comprises AlGaN on GaN (Ga-face).

The substrate 105 can comprise oxide single crystal materials such as sapphire (Al₂O₃ single crystal), zinc oxide (ZnO), and gallium lithium oxide (LiGaO₂), and Group IV semiconductor single crystals such as a silicon single crystal and cubic or hexagonal silicon carbide (SiC). Alternatively, a group III-V compound semiconductor single crystal material such as gallium phosphide (GaP) may also be used as a substrate material. The substrate 105 can also comprise other materials, such as InP.

An optional nucleation layer 106 is shown between the substrate 105 and the first layer 107. Nucleation layer 106 can comprise GaN, AlGaN, or AN.

A gate electrode 112 (which can also be on a gate dielectric to form a gate stack for MOS gate embodiments) is shown on a surface of the heterojunction 108/107. The gate electrode 112 can comprise a wide band-gap material, being either p, n doped or undoped, such as P-doped GaN for 2DEG electron devices or N-doped GaN for 2DHG devices. The gate electrode 112 can also be configured as metal gate (schottky gate). Gate electrode 112 is typically 0.2 μm to 1 μm thick, but can be thinner or thicker than this range. Reference 109 shown as a 2DEG channel 109 in FIG. 1A and throughout this Disclosure is understood to also represent a 2DHG channel on the case the HEMT is a 2DHG device.

A source 113 and a drain 114 are on opposite sides of the gate electrode 112. A patterned FS layer 130 comprising a wide band-gap semiconductor material is over the heterojunction 108/107 on at least a portion of the distance between the gate electrode 112 and the drain 114. The FS layer 130 is generally in a thickness range between 10 A and 500 A, and is in a thickness range between 50 to 150 A thick in some embodiments. In one particular embodiment, a single epitaxial deposition step followed by patterning can be used to form both the gate electrode 112 and the FS layer 130. In this embodiment the FS layer 130/gate electrode 112 is 200 to 500 A thick. Although not shown, FS layer 130 or FS layer portions in the case of multiple FS layer portions can utilize a variety of shapes, including rectangular, or irregular shapes such as comb-shaped.

HEMT 100 is one of the disclosed embodiments where the patterned FS layer is in direct contact with the heterojunction 108/107 including on a sidewall of the gate electrode 112 on the drain side of the gate electrode 112. This embodiment recognizes passivation materials including silicon nitride passivation have a low Ec (critical electric field) which can breakdown at lower electric fields when compared to wide-band-gap materials. The passivation in this conventional arrangement is thus recognized by disclosed embodiments to be the weak point of the whole HEMT structure, since the principal reason to use wide-band-gap materials such as GaN is their high Ec at which they avalanche breakdown. The patterned FS layer in direct contact with the heterojunction 108/107 avoids this problem of conventional HEMTs.

Moreover, HEMT 100 is one of the disclosed embodiments where the patterned FS layer 130 has at least two different thicknesses including a thicker thickness portion closer to the gate electrode 112 on the drain side as compared to a thinner portion further from the gate electrode 112 on the drain side. To create multiple thicknesses for the FS layer multiple mask/photolithography/etch steps are generally used. This embodiment recognizes since the electric field is the highest at the gate corner on the drain side, a thicker FS layer employed closer to the gate electrode reduces the high electric filed at the gate corner. This arrangement also provides a low on-resistance, as compared to a continuous (constant) thickness FS layer. Although not shown, a passivation layer (e.g., comprising silicon nitride) is generally over disclosed HEMTs that have patterned FS layers in direct contact with the heterojunction 108/107, such as HEMT 100 shown in FIG. 1A, and HEMTs 140, 160 and 180 disclosed below. However, mold compound added during assembly may also provide the same protective function as passivation.

FIG. 1B is a cross-sectional depiction of an example HEMT 140 having a patterned field shaping layer including FS layer portions 131a, 131b directly on the heterojunction, according to another example embodiment. FS layer portion 131a is thicker closer to the gate electrode 112 on the drain side as compared to a thinner FS layer portion 131b further from the gate electrode 112 on the drain side.

FIG. 1C is a cross-sectional depiction of an example HEMT 160 having a patterned field shaping layer comprising FS layer portions 132a, 132b directly on the heterojunction, according to yet another example embodiment. In this embodiment, a single epitaxial deposition step followed by patterning is used to form both the gate electrode 112 and the FS layer 132a, 132b, so that the gate electrode 112 and the FS layer 132a, 132b have the same thickness.

FIG. 1D is a cross-sectional depiction of a HEMT 180 having a patterned field shaping layer directly on the heterojunction, embodied as a MOS gate HEMT, according to yet another example embodiment. The MOS gate for HEMT 180 comprises gate electrode 112 on gate dielectric 117. Gate dielectric 117 can comprise silicon oxide, silicon oxynitride, silicon nitride, a silicate, or a high-k material (i.e., k-value>6) such as lead zirconate titanate (PZT) or barium strontium titanate (BST), or a combination or stack thereof.

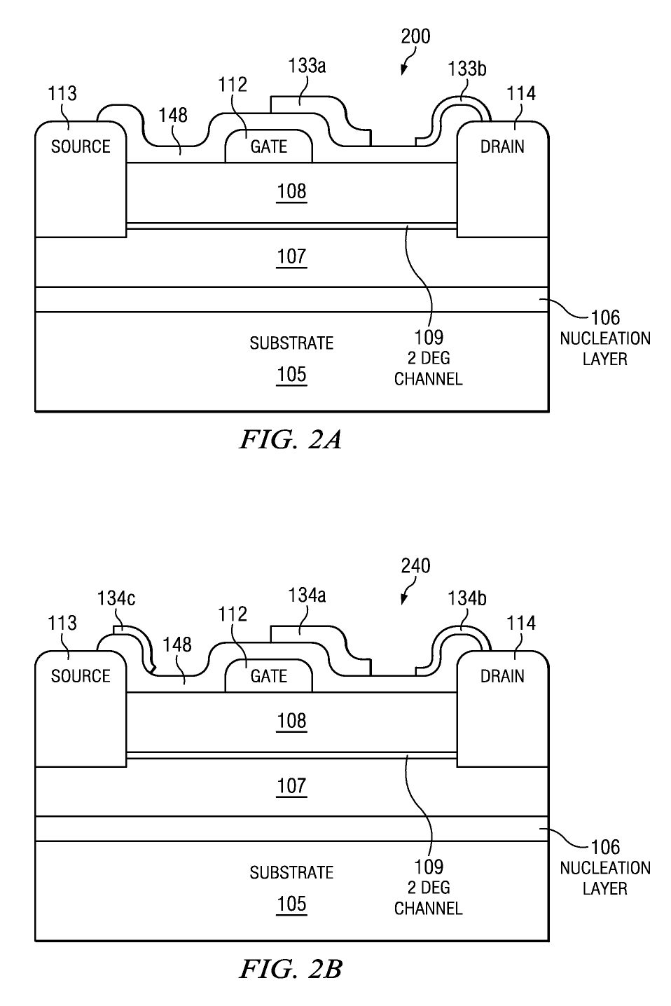

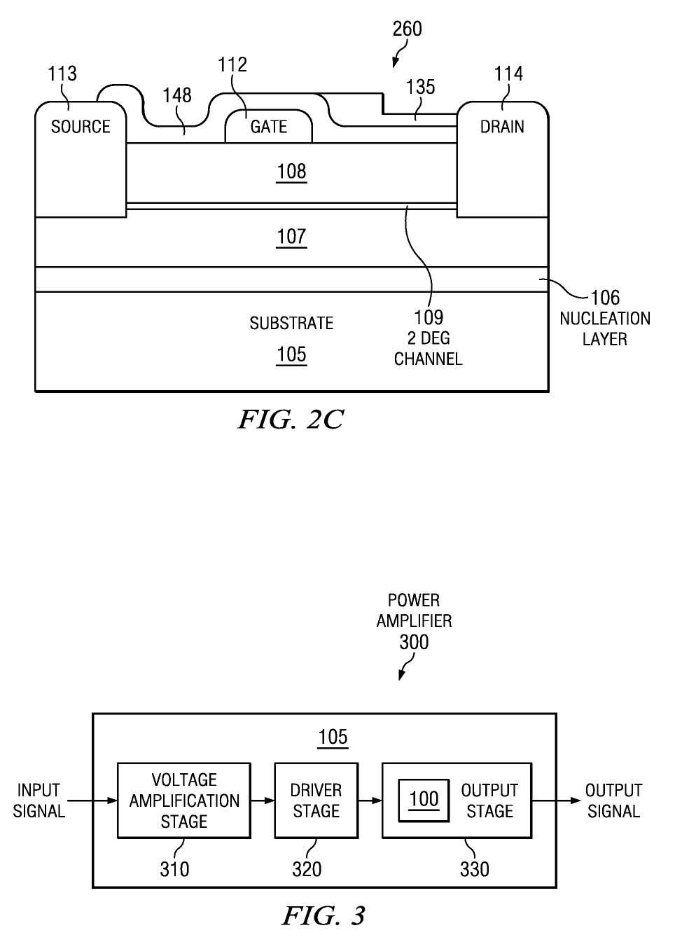

FIG. 2A is a cross-sectional depiction of a HEMT 200 having a passivation layer 148 on the HEMT including directly on the heterojunction 108/107 between the gate electrode 112 and the source 113, and between the gate electrode 112 and the drain 114, where the patterned FS layer comprises FS layer portions 133a, 133b is on the passivation layer 148, according to an example embodiment. The passivation layer 148 can comprise silicon nitride or silicon oxynitride. FS layer portion 133a is thicker closer to the gate electrode 112 on the drain side as compared to a thinner FS layer portion 133b further from the gate electrode 112 on the drain side. The patterned FS layer 133a, 133b in HEMT 200 (and HEMTs 240 and 260 described below) is electrically floating (in contrast to the FS layers in FIGS. 1A-D which are coupled to the second layer 108 of the heterojunction 108/107) analogous to how conventional field plates (FPs) are electrically configured.

FIG. 2B is a cross-sectional depiction of a HEMT 240 having a passivation layer 148 on the HEMT including directly on the heterojunction 108/107 between the gate electrode 112 and the source 113 and between the gate electrode 112 and the drain 114, where the patterned FS layer comprising FS layer portions 134a, 134b and 134c is on the passivation layer 148, according to another example embodiment. FS layer portion 134a is thicker closer to the gate electrode 112 on the drain side as compared to a thinner FS layer portion 134b further from the gate electrode 112 on the drain side, and thinner FS layer portion 134c further from the gate electrode 112 on the source side.

FIG. 2C is a cross-sectional depiction of a HEMT 260 having a passivation layer 148 on the HEMT including directly on the heterojunction 108/107 between the gate electrode 112 and the source 113 and between the gate electrode 112 and the drain 114, where the patterned FS layer 135 is on the passivation layer 148, according to yet another example embodiment. HEMT 260 is one disclosed embodiment where the patterned FS layer 135 has at least two different thicknesses including a thicker thickness portion closer to the gate electrode 112 on the drain side as compared to a thinner portion further from the gate electrode 112 on the drain side.

FIG. 3 is a simplified block diagram of a power amplifier 300 formed on a substrate 105 showing the different power amplifier stages comprising a voltage amplification stage 310, a driver stage 320 and an output stage 330. At least one disclosed HEMT having electric field shaping can be used in the output stage 330 of power amplifier 300.

### EXAMPLES

Disclosed embodiments are further illustrated by the following specific Examples, which should not be construed as limiting the scope or content of this Disclosure in any way.

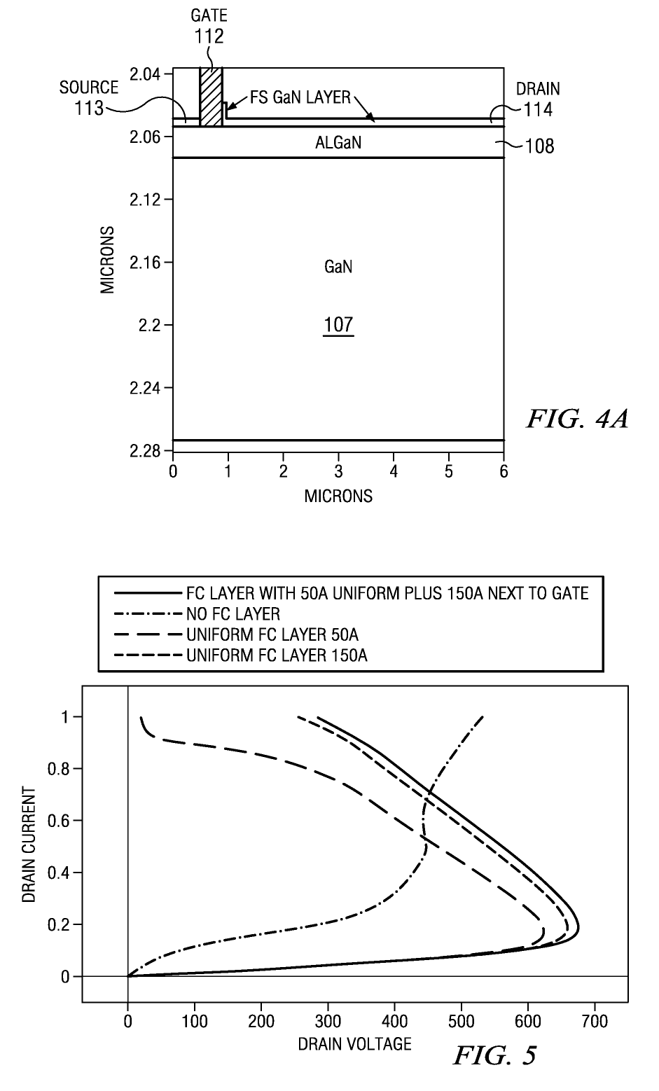

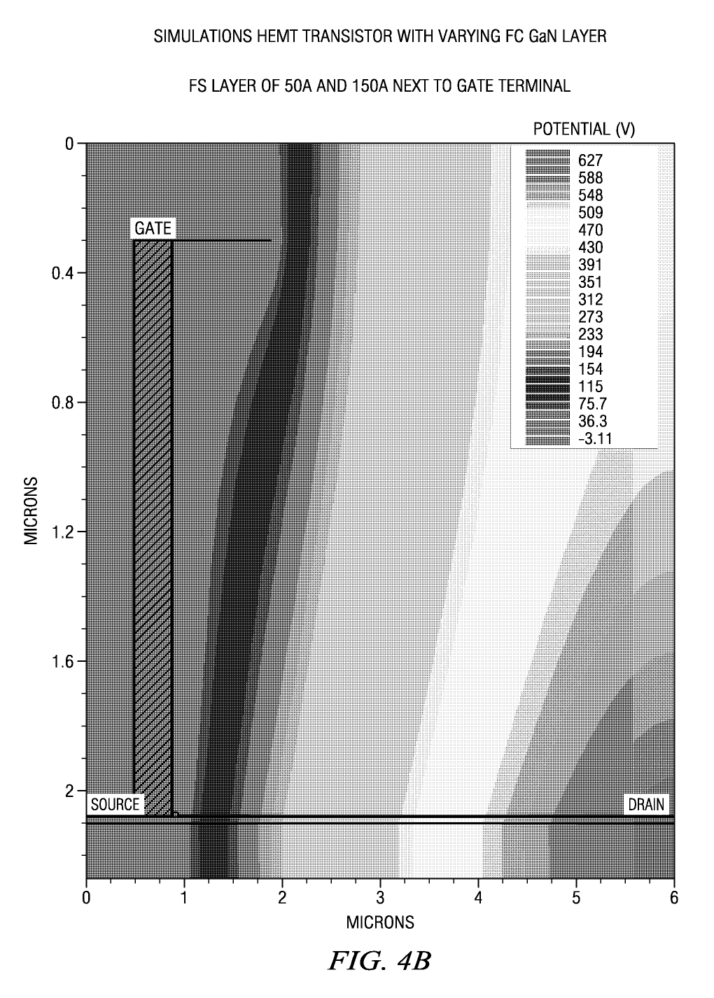

FIGS. 4A and 4B show a simplified cross-sectional depiction of a disclosed HEMT having a FS layer comprising GaN that is 50 A thick, except 150 A thick next to the gate electrode, and simulation results for this HEMT showing the voltage distribution along the voltage supporting region, respectively. The polarization layer used in the simulation had a mole fraction of x=0.3 in AlₓGa₁₋ₓN and a GaN FS layer. The HEMT was simulated for reverse breakdown voltage by applying potential at the drain with respect to the source, while the gate and source are shorted together. The resulting potential (V) near the gate electrode 112 on the drain side can be seen to be reduced to only about 200 V, which is significantly lower as compared to the potential near the drain 114.

FIG. 5 show simulated reverse breakdown voltage results for disclosed HEMTs including the HEMT shown in FIG. 4A (150 A FS layer next to gate electrode 112 on the drain side and 50 A otherwise), an HEMT having a uniform 150 A FS layer between gate electrode and drain, and an HEMT having a uniform 50 A FS layer between gate electrode and drain, and a control HEMT lacking a disclosed FS layer. Disclosed HEMTs all show a significant reverse breakdown voltage and leakage improvement as compared to the control HEMT.

Disclosed embodiments can be integrated into a variety of flows to form a variety of different semiconductor integrated circuit (IC) devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this Disclosure relates will appreciate that many other embodiments and variations of embodiments are possible within the scope of the claimed invention, and further additions, deletions, substitutions and modifications may be made to the described embodiments without departing from the scope of this Disclosure.

I claim:

1. A high electron mobility transistor (HEMT), comprising:
a substrate;
a heterojunction on said substrate including a first layer comprising a Group III-nitride semiconductor material interfaced to a second layer comprising a doped Group III-nitride semiconductor material;
a gate electrode on a surface of said heterojunction;
a source and a drain on opposite sides of said gate electrode, and
a patterned field shaping (FS) layer comprising a wide band-gap semiconductor material over said heterojunction on at least a portion between said gate electrode and said drain.

2. The HEMT of claim 1, wherein said patterned FS layer is contact with a sidewall of said gate electrode on a drain side of said gate electrode.

3. The HEMT of claim 1, wherein said Group III nitride semiconductor material comprises GaN and wherein said doped Group III nitride semiconductor material comprises AlGaN.

4. The HEMT of claim 3, wherein said Group III nitride semiconductor material comprises said GaN on said AlGaN.

5. The HEMT of claim 3, wherein said Group III nitride semiconductor material comprises said AlGaN on said GaN.

6. The HEMT of claim 1, wherein said patterned FS layer has at least two different thicknesses including a thicker portion closer to said gate region on a drain side as compared to a thinner portion further from said gate region on said drain side.

7. The HEMT of claim 1, wherein said gate electrode comprises said wide band-gap material.

8. The HEMT of claim 7, wherein said wide band-gap material comprises a GaN layer.

9. The HEMT of claim 8, wherein said GaN layer comprises p-type GaN layer.

10. The HEMT of claim 1, wherein said substrate comprises GaP, SiC, InP, silicon or sapphire.

11. The HEMT of claim 1, further comprising a passivation layer on said HEMT including directly on said heterojunction between said gate electrode and said source and between said gate electrode and said drain, wherein said patterned FS layer is on said passivation layer.

12. The HEMT of claim 1, wherein said HEMT comprises an enhancement mode HEMT.

13. The HEMT of claim 1, wherein said HEMT comprises a depletion mode HEMT.

14. The HEMT of claim 13, wherein said depletion mode HEMT comprises a MOS gate comprising said gate electrode on a gate dielectric.

15. A power amplifier, comprising:
a voltage amplifier block for receiving an input signal;
a driver stage block coupled to said voltage amplifier block, and
an output stage coupled to said driver stage block,
wherein said output stage includes at least one high electron mobility transistor (HEMT), said HEMT comprising:
a substrate;
a heterojunction on said substrate including a first layer comprising a Group III-nitride semiconductor material interfaced to a second layer comprising a doped Group III-nitride semiconductor material;
a gate electrode on a surface of said heterojunction;
a source and a drain on opposite sides of said gate electrode, and
a patterned field shaping (FS) layer comprising a wide band-gap semiconductor material over said heterojunction on at least of a portion between of said gate electrode and said drain.

16. The power amplifier of claim 15, wherein said patterned FS layer is contact with a sidewall of said gate electrode on a drain side of said gate electrode.

17. The power amplifier of claim 15, wherein said Group III nitride semiconductor material comprises GaN and wherein said doped Group III nitride semiconductor material comprises AlGaN.

18. The power amplifier of claim 15, wherein said patterned FS layer has at least two different thicknesses including a thicker portion closer to said gate region on a drain side as compared to a thinner portion further from said gate region on said drain side.

19. The power amplifier of claim 15, further comprising a passivation layer on said HEMT including directly on said heterojunction between said gate electrode and said source and between said gate electrode and said drain, wherein said patterned FS layer is on said passivation layer.

20. The power amplifier of claim 15, wherein said HEMT comprises a depletion mode HEMT, and wherein said depletion mode HEMT comprises a MOS gate comprising said gate electrode on a gate dielectric.
